(19) United States
(12) Patent Application Publication
(10) Pub. No.: US 2017/0110313 A1
(43) Pub. Date: Apr. 20, 2017

(54) IMPLEMENTING ATOMIC LAYER DEPOSITION FOR GATE DIELECTRICS

(71) Applicant: ASM IP Holding B.V., Almere (NL)

(72) Inventors: Fu Tang, Gilbert, AZ (US); Xiaoqiang Jiang, Tempe, AZ (US); Qi Xie, Lueven (BE); Michael Eugene Givens, Scottsdale, AZ (US); Jan Willem Maes, Wilrijk (BE); Jerry Chen, Chandler, AZ (US)

(21) Appl. No.: 15/286,503

(22) Filed: Oct. 5, 2016

Related U.S. Application Data
(60) Provisional application No. 62/242,804, filed on Oct. 16, 2015.

(51) Int. Cl. H01L 21/02; H01L 29/78; H01L 29/20; H01L 29/51; C23C 16/455; H01L 29/16

(52) U.S. Cl. CPC H01L 21/0228; H01L 21/02274; H01L 21/02211; H01L 21/02156; C23C 16/45544; H01L 29/16; H01L 29/20; H01L 29/517; H01L 29/78

(57) ABSTRACT

A method for depositing a thin film onto a substrate is disclosed. In particular, the method forms a transitional metal silicate onto the substrate. The transitional metal silicate may comprise a lanthanum silicate or yttrium silicate, for example. The transitional metal silicate indicates reliability as well as good electrical characteristics for use in a gate dielectric material.

### CROSS REFERENCE TO RELATED APPLICATION

The present application claims priority to U.S. Provisional Patent Application No. 62/242,804, entitled “Implementing Atomic Layer Deposition Gate Dielectrics for MOSFET Devices” and filed on Oct. 16, 2015, the contents of which are hereby incorporated herein by reference, to the extent such contents do not conflict with the present disclosure.

### FIELD OF INVENTION

The present disclosure generally relates to processes for manufacturing electronic devices. More particularly, the disclosure relates to forming a Transition Metal Silicate film through atomic layer deposition (ALD).

### BACKGROUND OF THE DISCLOSURE

Atomic layer deposition (ALD) is a method for depositing a thin film on a substrate through sequential distribution of various precursors. A conventional ALD method can take place in a reaction system comprising a reaction chamber, a substrate holder, a gas flow system, and an exhaust system. Growth of the thin film takes place when the precursors adsorb onto active sites on the substrate such that only a monolayer of the precursor forms on the substrate. Any excess precursor may then be expunged from the reaction chamber through the exhaust. Another precursor may be introduced to form another monolayer. The process may be repeated as needed to form a desired film of a desired thickness.

ALD processes have been particularly effective in forming gate dielectrics in complementary metal oxide semiconductor (CMOS) devices. For many years, silicon oxide (SiO₂) has been used for components in CMOS applications as transistor gate dielectrics and gate dielectrics. However, with the reduction in size of the components, SiO₂ has demonstrated problematic effects in the form of increased leakage currents. Controlling leakage current with the size constraints has proved challenging for SiO₂.

In the formation of gate dielectrics, a dielectric material with a high dielectric constant (“high-k dielectric”) has been shown to have the performance characteristics in order to achieve smaller device geometries while controlling leakage and other electrical criteria. With these desired goals in mind, U.S. Pat. No. 7,795,160 to Wang et al. discloses methods for controlled deposition of a conformal metal silicate film onto a substrate surface. Going away from the prior SiO₂ methods, the methods disclosed could be used to form, specifically, hafnium silicate (HfSiOₓ) and zirconium silicate (ZrSiOₓ) films for various applications, such as gate stacks in CMOS devices, dielectric layers in DRAM devices and components of other capacitor-based devices. HfSiOₓ and ZrSiOₓ offer thermal stability and device performance in integrated circuits in smaller device geometries.

Also going away from prior SiO₂ methods, U.S. Pat. No. 8,071,452 to Raisanen discloses a method for ALD deposition of a metal film layer in order for use in high-k dielectric materials. Specifically, a method for depositing a hafnium lanthanum oxide (HfLaO) layer is disclosed. The method allows a HfLaO dielectric layer to be engineered with a desired dielectric constant and/or other controllable characteristics.

As a result, a method for forming a transition metal film that attains desired dielectric constants as well as demonstrates reliability is desired.

### SUMMARY OF THE DISCLOSURE

In accordance with at least one embodiment of the invention, a method of forming a film is disclosed. The method comprises: providing a substrate for processing in a reaction chamber; performing a silicon precursor deposition onto the substrate; and performing a metal precursor deposition onto the substrate; wherein the silicon precursor deposition step is performed X times; wherein the metal precursor deposition step is performed Y times; wherein a transition metal silicate film is formed; wherein a metal precursor from the metal precursor deposition step comprises a metal atom bonded to a nitrogen atom or a carbon atom.

In accordance with at least one embodiment of the invention, a method of forming a transition metal silicate film is disclosed. The method comprises: providing a substrate for processing in a reaction chamber; performing a silicon precursor deposition onto the substrate, the performing the silicon precursor deposition comprising: pulsing a silicon precursor; purging the silicon precursor from the reaction chamber with a purge gas; pulsing an oxidizing precursor; and purging the oxidizing precursor from the reaction chamber with the purge gas; performing a metal precursor deposition onto the substrate, the performing the metal precursor deposition comprising: pulsing a metal precursor; purging the metal precursor from the reaction chamber with a purge gas; pulsing an oxidizing precursor; and purging the oxidizing precursor from the reaction chamber with the purge gas; wherein the silicon precursor deposition step is repeated X times; wherein the metal precursor deposition step is repeated Y times; and wherein a transition metal silicate film is formed; wherein the metal precursor comprises a metal atom bonded to a nitrogen atom or a carbon atom.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a diagram illustrating a method in accordance with at least one embodiment of the invention.

FIG. 2 is a diagram illustrating a method in accordance with at least one embodiment of the invention.

FIG. 3 is a diagram illustrating a method in accordance with at least one embodiment of the invention.

FIG. 4 is a diagram illustrating a method in accordance with at least one embodiment of the invention.

FIG. 5 is a graph illustrating growth rate and silicon incorporation as a function of pulsing ratio in accordance with at least one embodiment of the invention.

FIG. 6 is a chart illustrating a Rutherford Back Scattering analysis in accordance with at least one embodiment of the invention.

FIG. 7 is a schematic of a reaction system in accordance with at least one embodiment of the invention.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

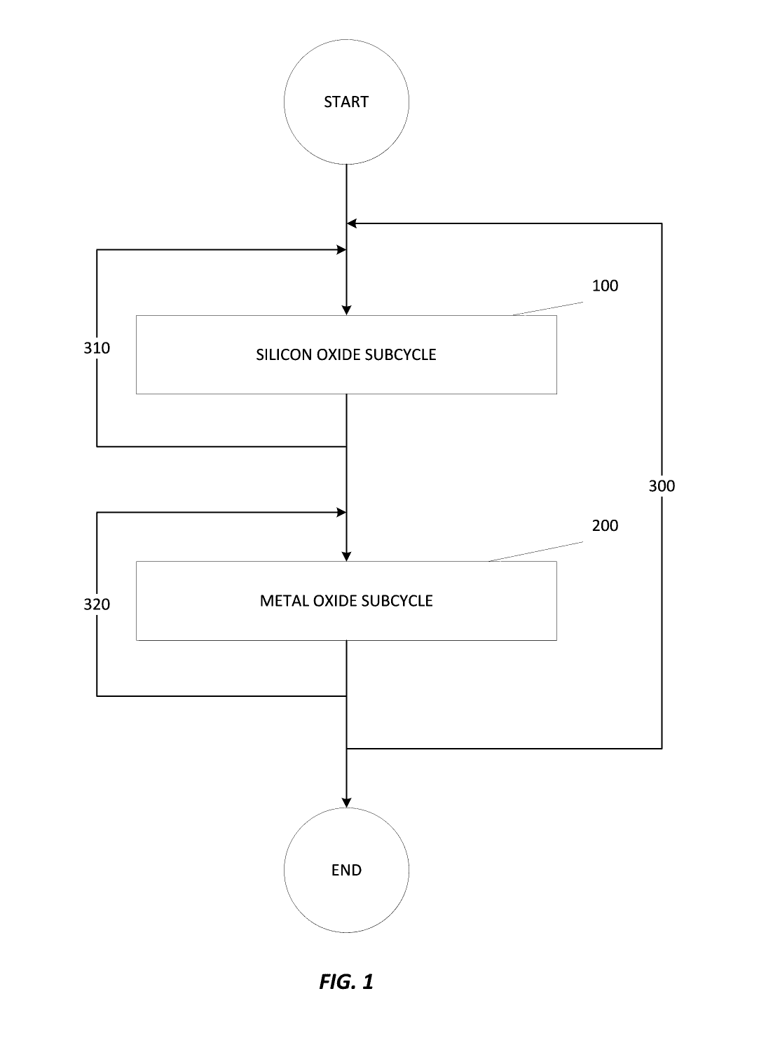

FIG. 1 illustrates a process in which a transition metal silicate film can be formed on a substrate according to at least one embodiment of the invention. The substrate may be a silicon substrate, a silicon-capped germanium substrate, a Ge substrate, a SiGe substrate, or a III-V semiconductor substrate (such as InGaAs). In order to form a metal silicate film, such as a Lanthanum Silicate (LaSiO) film, a master cycle may comprise two subcycles. One subcycle may be a silicon oxide subcycle 100, while the other subcycle may be a metal oxide subcycle 200. The silicon oxide subcycle 100 may be repeated via a repeat cycle 310, while the metal oxide subcycle 200 may be repeated via a repeat cycle 320. The entire process may be repeated via a master repeat cycle 300. In accordance with at least one embodiment, the silicon oxide subcycle 100 may be repeated X times via the repeat cycle 310 and the metal oxide subcycle 200 may be repeated Y times via the repeat cycle 320 in order to complete one master cycle. The ratio of X:Y may be used to adjust the growth rate of the LaSiO film.

In at least one embodiment of the invention, the order of the subcycles may be varied such that an order of the subcycles could be in a sandwich structure. For example, if pulse ratio of the silicon oxide subcycle to the lanthanum oxide subcycle equals 2:1; then precursor deposition may proceed as one silicon oxide subcycle 100, followed by a lanthanum oxide subcycle 200, and then a silicon oxide subcycle 100. In another embodiment of the invention, the order of the subcycles could be such that either subcycle could be first or last. Subcycles may be inserted at non-fixed ratios in order to effectively grade a composition of the film versus a vertical distance from the substrate.

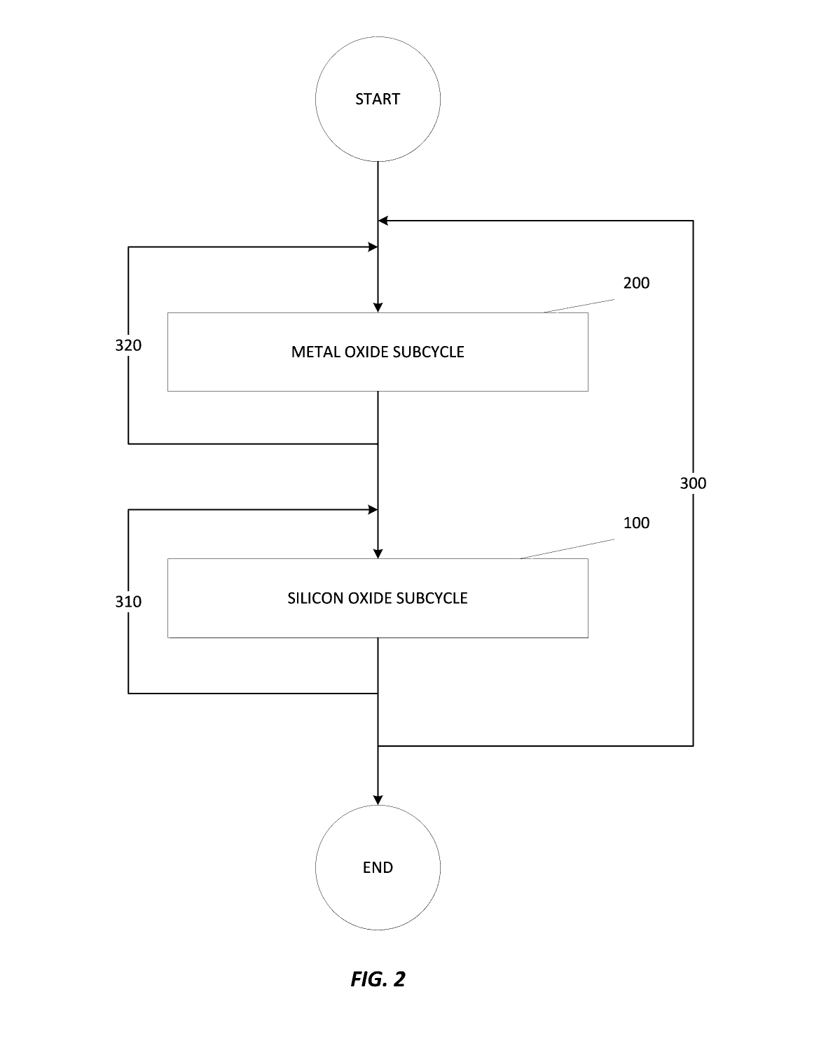

It may also be possible that different orders for subcycles result in a film with the similar properties. FIG. 2 illustrates a process in accordance with at least one embodiment of the invention, where a metal oxide subcycle 200 comes before a silicon oxide subcycle 100. In addition, in accordance with at least one embodiment of the invention, a lanthanum precursor pulse/purge followed by a silicon precursor pulse/purge, and then an oxygen precursor pulse/purge may result in a similar film as one produced by the sandwich order described above.

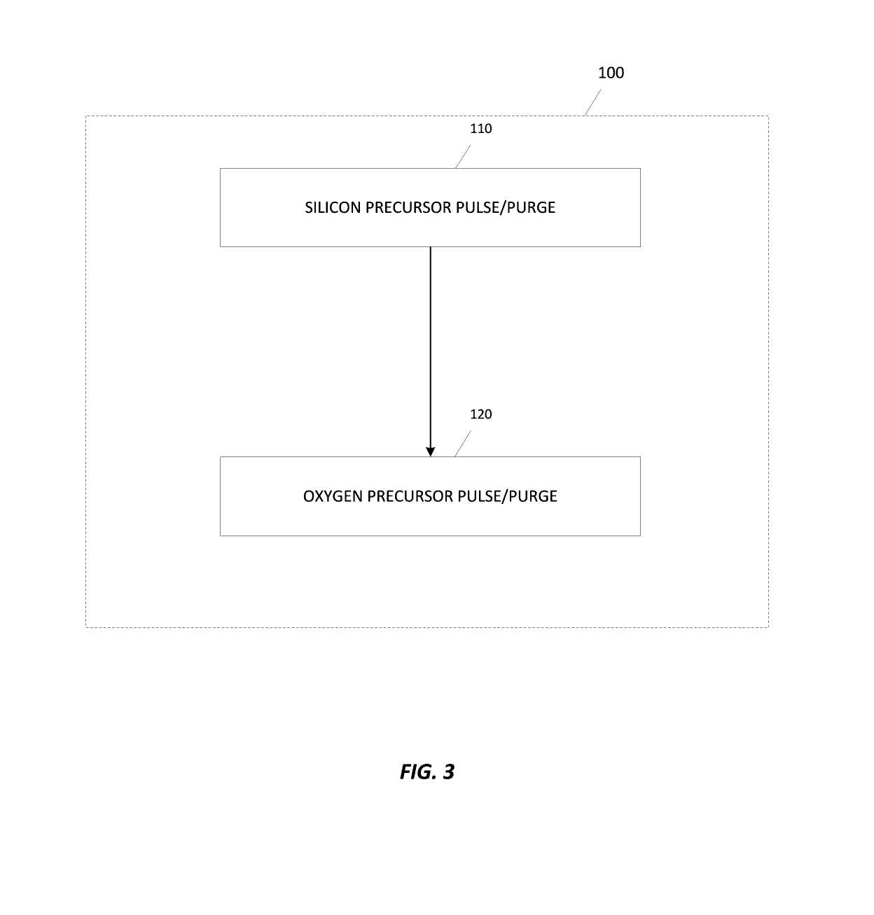

FIG. 3 illustrates a silicon oxide subcycle 100 in accordance with at least one embodiment of the invention. The silicon oxide subcycle 100 can comprise a Silicon (Si) precursor pulse/purge 110 and an oxygen precursor pulse/purge 120. The Si precursor may comprise at least one of the following: a silicon halide based precursor such as Silicon tetrachloride (SiCl₄), trichloro-silane (SiCl₃H), dichloro-silane (SiCl₂H₂), monochloro-silane (SiClH₃), hexachlorodisilane (HCDS), octachlorotrisilane (OCTS), silicon iodides, or silicon bromides; or an amino-based precursor, such as Hexakis(ethylamino)disilane (AHEAD) and SiH[N(CH₃)₂]₃(3DMASi), Bis(dialkylamino)silanes, such as BDEAS (bis(diethylamino)silane); and mono(alkylamino)silanes, such as di-isopropylaminosilane; or an oxysilane based precursor, such as tetraethoxysilane Si(OC₂H₅)₄. The typical temperatures for this process range from 100-450° C., or from 150-400° C., or from 175-350° C., or from 200-300° C., while pressures may range from 1 to 10 Torr.

In other embodiments consistent with the invention, the oxygen precursor pulse/purge 120 may involve a pulse and purge of at least one of: water (H₂O); diatomic oxygen (O₂); hydrogen peroxide (H₂O₂); ozone (O₃); oxygen plasma; atomic oxygen (O); oxygen radicals; or methyl alcohol (CH₃OH). It may be possible that different oxidizing precursors could be used for the different cycles; for example, O₃ may be used for the silicon oxide subcycle, while water can be used for the lanthanum oxide subcycle. In other embodiments of the invention, it may be possible to use an oxygen source that does not comprise ozone, O₂, H₂O₂, H₂O, methyl alcohol, or oxygen plasma.

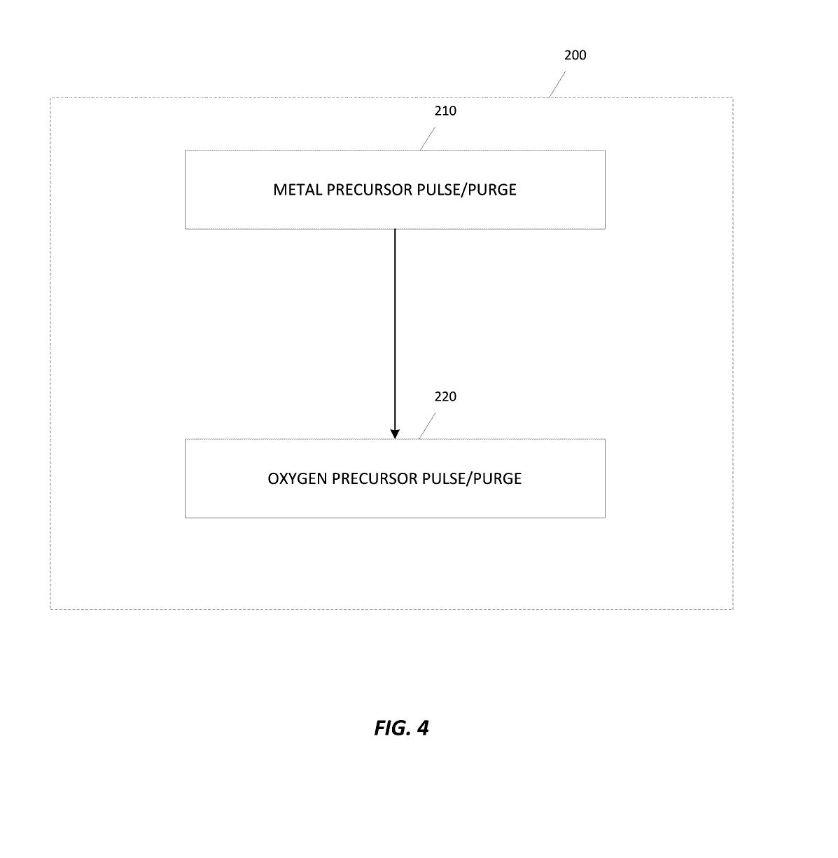

FIG. 4 illustrates a metal oxide subcycle 200 in accordance with at least one embodiment of the invention. The metal oxide subcycle (or a rare earth metal precursor subcycle) 200 may comprise a metal precursor pulse/purge 210 and an oxygen precursor pulse/purge 220. In some embodiments of the invention, a rare earth metal precursor (such as Lanthanum (La), Scandium (Sc), Yttrium (Y), Ce, Pr, Nd, Sm, Eu, Gd, Tb, Dy, Ho, Er, Tm, Yb or Lu, for example) may comprise a bond between the rare earth metal and Nitrogen or a bond between rare earth metal and Carbon. In some embodiments of the invention, the rare earth metal precursor may comprise a bidentate ligand bonded to lanthanum through two nitrogen atoms. In some embodiments of the invention, the rare earth metal in the rare earth metal precursor (e.g., lanthanum) has an oxidation state of +III. In some embodiments of the invention, the rare earth metal precursor has three organic ligands, such as ligands containing nitrogen or carbon. In some embodiments, the rare earth metal precursor (e.g., lanthanum) may not comprise Silicon or Germanium. In some embodiments, the metal precursor may comprise a metal atom bonded to a nitrogen atom or a carbon atom.

In at least one embodiment of the invention, a metal precursor in the metal precursor pulse/purge 210 may be one of the following: an amidinate based precursor, such as Lanthanum formamidinate (La(FAMD)₃) or tris(N,N′-diisopropylacetamidinato)lanthanum (La(iPrAMD)₃); a diketonate precursor, such as (La(THD)₃); a Cp(cyclopentadienyl)-based precursor such as Tris(isopropyl-cyclopentadienyl)lanthanum (La(iPrCp)₃); or an amido-based chemistry such as tris(bistrimethylsilylamido)-lanthanum (La[N(SiMe₃)₂]₃); or hybrid combinations of the above. In other embodiments consistent with the invention, the metal precursor may be a lanthanum or other rare earth metal precursor having a bond between nitrogen, such as a lanthanum amidinate, for example. The amidinate compounds may comprise delocalized electrons that result in the bond between the nitrogen and the lanthanum or rare earth metal. In other embodiments consistent with the invention, the metal precursor may be a lanthanum or other rare earth metal precursor having a bond with carbon, such as a lanthanum cyclopentadienyl, for example. This metal precursor may comprise delocalized electrons, which are considered to be compounds, in which the bond between the carbon and the lanthanum or rare earth forms. In other embodiments consistent with the invention, the metal precursor may be a lanthanum or other rare earth metal precursor having a bond with both nitrogen and carbon, such as a lanthanum amidinate and a lanthanum cyclopentadienyl compound, for example.

In other embodiments consistent with the invention, the oxygen precursor pulse/purge 220 may involve at least one of: water (H₂O), diatomic oxygen (O₂), hydrogen peroxide (H₂O₂), ozone (O₃), oxygen plasma, oxygen radicals, atomic oxygen, or methyl alcohol (CH₃OH). The metal oxide subcycle 200 may be substituted with an yttrium oxide subcycle or another element's subcycle depending on what is the final desired product. Other elements could be lanthanides, erbium, erbium oxide, magnesium, magnesium oxide, scandium, or scandium oxide, among others. These other materials may also be preferable as they demonstrate an ability to cause the Vₜ shift. For yttrium, the yttrium subcycle may comprise a yttrium pulse, a purge of the yttrium precursor, a H₂O pulse, and a purge of the H₂O precursor. The yttrium precursor could be one of the following: a Cp(cyclopentadienyl)-based chemistry, such as Y(EtCp)₃ and tris(methylcyclopentadienyl)yttrium (Y(MeCp)₃); an amidinate-based precursor, such as Tris(N,N′-diisopropylacetamidinato) Yttrium (TDIPAY); a diketonate precursor, such as (Y(THD)₃) and tris(2,2,6,6-tetramethyl-3,5-octanedionato)Yttrium (Y(tmod)₃); or an amide-based precursor, such as Tris[N,N-bis(trimethylsilyl)amide]yttrium. Typical temperatures for this process range from 100-450° C., or from 150-400° C., or from 175-350° C., or from 200-300° C., with pressures ranging from 1 to 10 Torr.

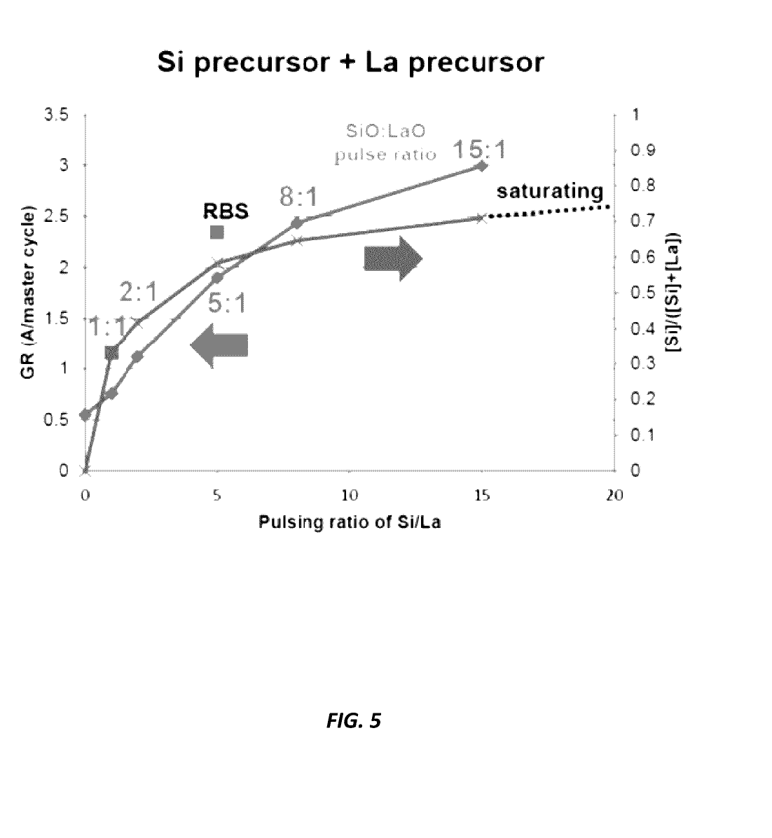

The pulse ratio X:Y of the silicon and metal oxide subcycles can allow for incorporation of Silicon (Si) into the metal silicate film. The pulse ratio X:Y may range to be 5:1, 7:1, 10:1, and 20:1. FIG. 5 illustrates a graph of silicon incorporation based on different pulse ratios X:Y. For higher X:Y pulse ratios, the incorporation of Silicon is greater, resulting in a higher silicon content. Control of the pulse ratio can enable Si incorporation to exceed 65%. Si content may vary from low levels to high levels. For example, the silicon content may range as being greater than 5 at-% Si, greater than 10 at-% Si, greater than 15 at-% Si, or greater than 20 at-% Si. A pure silicon oxide film may have a silicon content of approximately 33 at-%. In the case of forming a LaSiO film, a higher Si content may reduce the hygroscopic property of LaO and also improve the compatibility with the following high-k growth. The Silicon incorporation in excess of 65% is significantly higher than that for Aluminum Silicates (AlSiO), which tend to average about 30-40% (for TMA vs. AlCl₃ processes).

An additional benefit attained through at least one embodiment of the invention includes a lower carbon impurity level. Carbon is considered as a trap center and may degrade the performance of a device formed using the deposited film. As a result, a lower carbon level may be preferable.

Carbon may be formed easily if strong oxygen reactants, such as ozone or oxygen plasmas, are used. These strong reactants may result in greater oxidation of the substrate. Conventional LaOx films deposited through ALD indicate a high carbon impurity level between 15-20%. In addition, conventional LaOx films may also show high hydroxide impurities as well as low silicon incorporation.

In accordance with at least one embodiment of the invention, a combination of a silicon halide precursor, a rare earth precursor having a bond with a nitrogen/carbon atom, a proper oxygen precursor (such as water), and a high mobility channel material may be the reason for a lower carbon impurity level. The proper oxygen precursor may result in less oxidation of the substrate, potentially providing for a good surface or interface for subsequent deposition of additional materials, such as a high-k material formed by ALD.

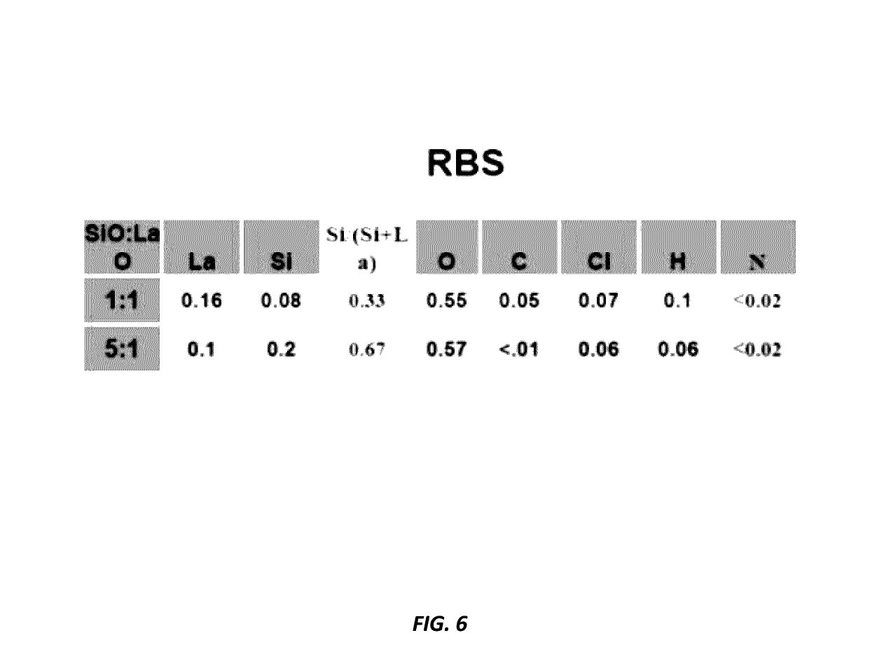

As shown in FIG. 6, LaSiO films deposited through embodiments in accordance with the invention indicate a much lower carbon impurity level less than 5% depending on the pulse ratio X:Y. These percentages are determined through the Rutherford Back-Scattering (RBS) analysis method. The LaSiO film may also demonstrate less than 10 at-% of hydrogen impurities, less than about 5 at-% of carbon impurities, and/or less than about 2 at-% of nitrogen impurities. In accordance with at least one embodiment of the invention, the LaSiO film may have a hydrogen content of less than 20 at-%, less than 15 at-%, less than 10 at-%, or less than 5 at-%. In accordance with at least one embodiment of the invention, the LaSiO film may have a carbon content of less than 10 at-%, less than 5 at-%, less than 2 at-%, or less than 1 at-%. In accordance with at least one embodiment of the invention, the LaSiO film may have a nitrogen content of less than 10 at-%, less than 5 at-%, less than 2 at-%, or less than 1 at-%.

In accordance with at least one embodiment of the invention, a lanthanum hydroxide film (La(OH)₃) may be formed. In at least one embodiment of the invention, for a pure lanthanum hydroxide (La(OH)₃) film, the hydrogen content could be less than 43%. In accordance with at least one embodiment of the invention, a lanthanum hydroxide film may have hydrogen impurities, ranging from less than 20 mol-% of hydroxide (OH), less than 15 mol-% of hydroxide (OH), less than 10 mol-% of hydroxide (OH), or less than 5 mol-% of hydroxide (OH).

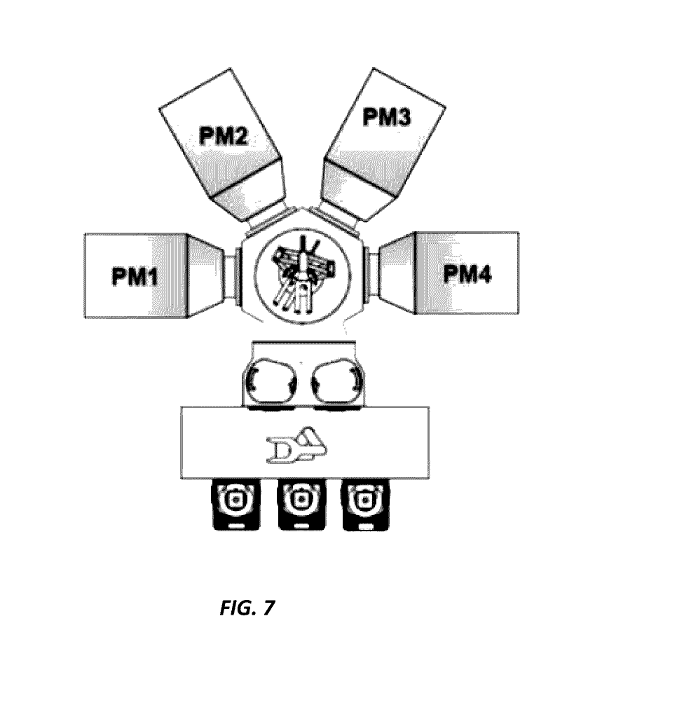

FIG. 7 illustrates a reaction system setup capable of performing the method according to at least one embodiment of the invention. The reaction system includes four process modules. Process modules (PM) may include Pulsar® 3000 modules or Horizon modules provided by ASM International N.V. Other reaction system setups may include a mini-batch reactor, a dual chamber module reactor, a batch reactor, a cross-flow reactor, or a showerhead reactor. A wafer handling system may transfer a processed wafer to the different modules. In one process module, an interface layer for a Germanium/Silicon Germanium or a III-V substrate (such as InGaAs) may be formed via a method in accordance with at least one embodiment of the invention. In another process module, other development processes may take place, such as surface passivation of Ge/SiGe channels or a III-V substrate (such as InGaAs).

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

We claim:

1. A method of forming a film comprising:
providing a substrate for processing in a reaction chamber;
performing a silicon precursor deposition onto the substrate; and
performing a metal precursor deposition onto the substrate;
wherein the silicon precursor deposition step is performed X times;
wherein the metal precursor deposition step is performed Y times;
wherein a transition metal silicate film is formed;
wherein a metal precursor from the metal precursor deposition step comprises a metal atom bonded to a nitrogen atom or a carbon atom.

2. The method of claim 1, wherein the performing the silicon precursor deposition step further comprises:
pulsing a silicon precursor;
purging the silicon precursor from the reaction chamber with a purge gas;
pulsing an oxidizing precursor; and
purging the oxidizing precursor from the reaction chamber with the purge gas.

3. The method of claim 2, wherein the silicon precursor comprises at least one of: a silicon halide based precursor such as Silicon tetrachloride (SiCl₄), trichloro-silane (SiCl₃H), dichloro-silane (SiCl₂H₂), monochloro-silane (SiClH₃), hexachlorodisilane (HCDS), octachlorotrisilane (OCTS), silicon iodides, or silicon bromides; an amino-based precursor, such as Hexakis(ethylamino)disilane (AHEAD) and SiH[N(CH₃)₂]₃(3DMASi); Bis(dialkylamino)silanes, such as BDEAS (bis(diethylamino)silane); a mono(alkylamino)silanes, such as di-isopropylaminosilane; or an oxysilane based precursor, such as tetraethoxysilane Si(OC₂H₅)₄.

4. The method of claim 2, wherein the oxidizing precursor comprises at least one of: water (H₂O); hydrogen peroxide (H₂O₂); oxygen (O₂); ozone (O₃); oxygen plasma; or methyl alcohol (CH₃OH).

5. The method of claim 1, wherein the performing the metal precursor deposition step further comprises:
pulsing a metal precursor;
purging the metal precursor from the reaction chamber with a purge gas;
pulsing an oxidizing precursor; and
purging the oxidizing precursor from the reaction chamber with the purge gas.

6. The method of claim 5, wherein the metal precursor comprises at least one of: lanthanum;
yttrium; an amidinate-based precursor, such as Lanthanum formamidinate (La(FAMD)₃), tris(N,N′-diisopropylacetamidinato)lanthanum (La(iPrAMD)₃), or Tris(N,N′-diisopropylacetamidinato) Yttrium (TDIPAY); a Cp(cyclopentadienyl)-based precursor, such as Tris(isopropyl-cyclopentadienyl) lanthanum (La(iPrCp)₃), Y(EtCp)₃, or tris(methylcyclopentadienyl)yttrium (Y(MeCp)₃); an amido-based chemistry, such as tris(bistrimethylsilylamido)-lanthanum (La[N(SiMe₃)₂]₃); a diketonate based precursor, such as (La(THD)₃), (Y(THD)₃), or tris(2,2,6,6-tetramethyl-3,5-octanedionato)Yttrium (Y(tmod)₃); or an amide-based precursor, such as Tris[N,N-bis(trimethylsilyl)amide]yttrium.

7. The method of claim 5, wherein the oxidizing precursor comprises at least one of: water (H₂O); hydrogen peroxide (H₂O₂); oxygen (O₂); ozone (O₃); oxygen plasma; atomic oxygen (0); oxygen radicals; or methyl alcohol (CH₃OH).

8. The method of claim 2, wherein the purge gas comprises at least one of: nitrogen (N₂) and Argon (Ar).

9. The method of claim 5, wherein the purge gas comprises at least one of: nitrogen (N₂) and Argon (Ar).

10. The method of claim 1, wherein the performing the silicon precursor deposition step and the performing the metal precursor deposition step are repeated until the transition metal silicate film reaches a desired thickness.

11. The method of claim 1, wherein the method is performed using an atomic layer deposition (ALD) process.

12. The method of claim 1, wherein the transition metal silicate film comprises one of: a lanthanum silicate, a yttrium silicate, a magnesium silicate, an erbium silicate, or another rare earth metal silicate.

13. The method of claim 1, wherein the transition metal silicate film formed comprises less than about 20 at-% of hydrogen impurities, less than about 15 at-% of hydrogen impurities, less than about 10 at-% of hydrogen impurities, or less than about 5 at-% of hydrogen impurities.

14. The method of claim 1, wherein the transition metal silicate film formed comprises less than about 10 at-% of carbon impurities, less than about 5 at-% of carbon impurities, less than about 2 at-% of carbon impurities, or less than about 1 at-% of carbon impurities.

15. The method of claim 1, wherein the transition metal silicate film formed comprises less than about 10 at-% of nitrogen impurities, less than about 5 at-% of nitrogen impurities, less than about 2 at-% of nitrogen impurities, or less than about 1 at-% of nitrogen impurities.

16. The method of claim 5, wherein the metal precursor comprises an amidinate precursor.

17. The method of claim 1, wherein the transition metal silicate film is formed at a reaction temperature from 100-450° C., from 150-400° C., from 175-350° C., or from 200-300° C.

18. The method of claim 1, wherein an extent of silicon integration into the transition metal silicate film is dependent on a ratio of X to Y.

19. The method of claim 1, wherein the substrate comprises at least one of: a silicon substrate, a silicon-capped germanium substrate, a Ge substrate, a SiGe substrate, or a III-V semiconductor substrate.

20. A method of forming a transition metal silicate film comprising:
providing a substrate for processing in a reaction chamber;
performing a silicon precursor deposition onto the substrate, the performing the silicon precursor deposition comprising:
pulsing a silicon precursor;
purging the silicon precursor from the reaction chamber with a purge gas;
pulsing an oxidizing precursor; and
purging the oxidizing precursor from the reaction chamber with the purge gas;
performing a metal precursor deposition onto the substrate, the performing the metal precursor deposition comprising:
pulsing a metal precursor;
purging the metal precursor from the reaction chamber with a purge gas;
pulsing an oxidizing precursor; and
purging the oxidizing precursor from the reaction chamber with the purge gas;
wherein the silicon precursor deposition step is repeated X times;
wherein the metal precursor deposition step is repeated Y times; and
wherein a transition metal silicate film is formed;
wherein the metal precursor comprises a metal atom bonded to a nitrogen atom or a carbon atom.

21. The method of claim 20, wherein the silicon precursor comprises at least one of: a silicon halide, such as silicon tetrachloride (SiCl₄), trichloro-silane (SiCl₃H), dichloro-silane (SiCl₂H₂), monochloro-silane (SiClH₃), hexachlorodisilane (HCDS), octachlorotrisilane (OCTS), silicon iodides, or silicon bromides; an amino-based precursor, such as Hexakis(ethylamino)disilane (AHEAD) and SiH[N(CH₃)₂]₃(3DMASi); a Bis(dialkylamino)silane, such as BDEAS (bis(diethylamino)silane); a mono(alkylamino)silane, such as di-isopropylaminosilane; or an oxysilane based precursor, such as tetraethoxysilane Si(OC₂H₅)₄.

22. The method of claim 20, wherein the metal precursor comprises at least one of: lanthanum; yttrium; an amidinate-based precursor, such as Lanthanum formamidinate (La(FAMD)₃), tris(N,N′-diisopropylacetamidinato)lanthanum (La(iPrAMD)₃), or Tris(N,N′-diisopropylacetamidinato) Yttrium (TDIPAY); a Cp(cyclopentadienyl)-based precursor, such as Tris(isopropyl-cyclopentadienyl) lanthanum (La(iPrCp)₃), Y(EtCp)₃, or tris(methylcyclopentadienyl)yttrium (Y(MeCp)₃); an amido-based chemistry, such as tris(bistrimethylsilylamido)-lanthanum (La[N(SiMe₃)₂]₃); a diketonate based precursor, such as (La(THD)₃), (Y(THD)₃), or tris(2,2,6,6-tetramethyl-3,5-octanedionato)Yttrium (Y(tmod)₃); or an amide-based precursor, such as Tris[N,N-bis(trimethylsilyl)amide]yttrium.

23. The method of claim 20, wherein the oxidizing precursor comprises at least one of: water (H₂O); hydrogen peroxide (H₂O₂); oxygen (O₂); ozone (O₃); oxygen plasma; atomic oxygen (O);
oxygen radicals; or methyl alcohol (CH₃OH).

24. The method of claim 20, wherein the transition metal silicate film is formed at a reaction temperature from about 100-450° C., or from 150-400° C., or from 175-350° C., or from 200-300° C.

25. The method of claim 20, wherein an extent of silicon integration into the transition metal silicate film is dependent on a ratio of X to Y, the ratio being approximately 5:1, approximately 10:1, approximately 15:1, or approximately 20:1.

26. The method of claim 20, wherein the method is performed using an atomic layer deposition (ALD) process.

27. The method of claim 20, wherein the purge gas comprises at least one of: nitrogen (N₂) and Argon (Ar).

28. The method of claim 20, wherein the transition metal silicate film comprises one of: a lanthanum silicate, a yttrium silicate, a magnesium silicate, an erbium silicate, or another rare earth metal silicate.

29. The method of claim 20, wherein the substrate comprises at least one of: a silicon substrate, a silicon-capped germanium substrate, a Ge substrate, a SiGe substrate, or a III-V semiconductor substrate.

30. A reaction chamber, wherein the reaction chamber is configured to perform the method of claim 20.
